(19) United States
(12) Patent Application Publication
(10) Pub. No.: US 2019/0027709 A1
(43) Pub. Date: Jan. 24, 2019

(54) METHOD FOR MANUFACTURING FLEXIBLE ORGANIC LIGHT EMITTING DIODE(OLED) DISPLAY DEVICE

(71) Applicant: WUHAN CHINA STAR OPTOELECTRONICS SEMICONDUCTER DISPLAY TECHNOLOGY CO., LTD., Wuhan, Hubei (CN)

(72) Inventors: Ming ZHANG, Wuhan (CN); Gaozhen WANG, Wuhan (CN)

(21) Appl. No.: 15/580,093

(22) PCT Filed: Nov. 16, 2017
(86) PCT No.: PCT/CN2017/111254

§ 371 Date: Dec. 6, 2017

(30) Foreign Application Priority Data
Jul. 24, 2017 (CN) 201710606853.3

(51) Int. Cl. H01L 51/56; H01L 27/32; H01L 51/00; G03F 7/16; G03F 7/09; G03F 7/095; G03F 7/20; G03F 7/26

(52) U.S. Cl. CPC H01L 51/56; H01L 27/3246; H01L 51/0097; G03F 7/16; G03F 7/094; H01L 2251/558; G03F 7/20; G03F 7/26; H01L 2251/301; H01L 2251/303; H01L 2251/5338; G03F 7/095

(57) ABSTRACT

The present invention provides a method for manufacturing a flexible OLED display device, the method comprises: forming an organic film layer on the substrate and defining a plurality of separating pillars by patterning; forming an inorganic film layer on the substrate and defining a plurality of separating films by patterning the inorganic film layer, to cover the separating pillars; and coating a first photoresist on the substrate.

### BACKGROUND OF INVENTION

### Field of Invention

The present invention relates to displays, and particularly to a method for manufacturing a flexible OLED display device.

### Description of Prior Art

Compared with liquid crystal displays (LCD), OLED display devices have many advantages such as active light, fast response times, wide viewing angles, high brightness, wide color range, and thinness.

As popularity of the flexible OLED increases, development of flexible OLED is also increasing. Currently, the OLED display devices are still made by evaporating, because masks deform, size of an evaporating substrate is difficult to match with size of an array substrate. A cutting process is used from an array substrate process to an evaporating process, and a photoresist is used to avoid debris made from the cutting process from entering into an evaporation chamber. So the photoresist is coated on a pixel defining layer to protect the pixel defining layer, and is peeled off by a stripping agent after the cutting process.

In order to reduce evaporative color mixing/crosstalk problems in an electroluminescent layer, thickness of the pixel defining layer is typically measured in micron, but the product flexibility in this thickness made of inorganic layer may be threatened. Both the pixel defining layer and the photoresist are made of organic materials, the photoresist is peeled off by mistake by the stripping agent to contaminate the evaporation chamber and affect continuity and stability of films during film packaging.

In conclusion, when the photoresist is peeled off by the stripping agent after the cutting process in a conventional manufacturing method for a flexible OLED display device, because both the pixel defining layer and the photoresist are made of organic materials, the photoresist is peeled off by mistake by the stripping agent to contaminate the evaporation chamber and affect continuity and stability of films during film packaging.

### SUMMARY OF INVENTION

The application mainly provides a method for manufacturing a flexible OLED display device to avoid a problem of the photoresist peeled off by mistake by the stripping agent.

For the above-mentioned objective, the present disclosure employs the following technical schemes.

A method for manufacturing a flexible OLED display device comprises a step of forming an anode metal layer on a substrate, and further comprises:

a step S101 of forming an organic film layer on the substrate and defining a plurality of separating pillars by patterning the organic film layer;

a step S102 of forming an inorganic film layer on the substrate and defining a plurality of separating films by patterning the inorganic film layer, to cover the separating pillars; and

a step S103 of coating a first photoresist on the substrate;

wherein an identical photomask is configured to form the organic film layer and form the inorganic film layer.

In the method for manufacturing the flexible OLED display device, the step S101 comprises:

coating a second photoresist on the organic film layer, exposing and developing the second photoresist to form a second photoresist pattern, etching the organic film layer not covered by the second photoresist, and peeling off the second photoresist arranged on a surface of the organic film layer to define the separating pillars.

In the method for manufacturing the flexible OLED display device, the step S102 comprises:

coating a third photoresist on the inorganic film layer, exposing and developing the third photoresist to form a third photoresist pattern, etching the inorganic film layer not covered by the third photoresist, and peeling off the third photoresist arranged on a surface of the inorganic film layer to define the separating films.

In the method for manufacturing the flexible OLED display device, the separating films are arranged on surfaces of the separating pillars.

In the method for manufacturing the flexible OLED display device, the anode metal layer comprises a plurality of anode plates arranged in an array, each of the separating pillars and one of the separating films corresponding to the separating pillar is arranged between two of the anode plates adjacent to each other.

In the method for manufacturing the flexible OLED display device, the inorganic film layer is made of one or more of Al2O3, SiNx, and SiOx.

In the method for manufacturing the flexible OLED display device, a thickness of the separating films is less than a thickness of the separating pillars.

In the method for manufacturing the flexible OLED display device, the thickness of the separating films is less than or equal to 0.5 μm.

A method for manufacturing a flexible OLED display device comprising a step of forming an anode metal layer on a substrate, and further comprising:

a step S101 of forming an organic film layer on the substrate and defining a plurality of separating pillars by patterning the organic film layer;

a step S102 of forming an inorganic film layer on the substrate and defining a plurality of separating films by patterning the inorganic film layer, to cover the separating pillars; and

a step S103 of coating a first photoresist on the substrate.

In the method for manufacturing the flexible OLED display device, the step S101 comprises:

coating a second photoresist on the organic film layer, exposing and developing the second photoresist to form a second photoresist pattern, etching the organic film layer not covered by the second photoresist, and peeling off the second photoresist arranged on a surface of the organic film layer to define the separating pillars.

In the method for manufacturing the flexible OLED display device, the step S102 comprises:

coating a third photoresist on the inorganic film layer, exposing and developing the third photoresist to form a third photoresist pattern, etching the inorganic film layer not covered by the third photoresist, and peeling off the third photoresist arranged on a surface of the inorganic film layer to define the separating films.

In the method for manufacturing the flexible OLED display device, the separating films are arranged on surfaces of the separating pillars.

In the method for manufacturing the flexible OLED display device, the anode metal layer comprises a plurality of anode plates arranged in an array, each of the separating pillars and one of the separating films corresponding to the separating pillar is arranged between two of the anode plates adjacent to each other.

In the method for manufacturing the flexible OLED display device, the inorganic film layer is made of one or more of Al2O3, SiNx, and SiOx.

In the method for manufacturing the flexible OLED display device, a thickness of the separating films is less than a thickness of the separating pillars.

In the method for manufacturing the flexible OLED display device, the thickness of the separating films is less than or equal to 0.5 μm.

A flexible OLED display device manufactured by the method above, the flexible OLED display device comprises a substrate, an anode layer, a pixel defining layer, a transmission layer, a light emitting layer, and a cathode layer, wherein the pixel defining layer comprises a plurality of separating pillars and a plurality of separating films.

Beneficial effects of the present invention is compared with the prior art method for manufacturing the flexible OLED display device, this application provides a method for manufacturing a flexible OLED display device, a plurality of separating films is formed on a substrate with an anode metal layer and a plurality of separating films covers the separating pillars to separate sub pixels, the separating films with a thinner thickness separates a photoresist and the separating pillars made of organic materials. After a cutting process, when the first photoresist formed on a surface of the substrate is peeled off by a stripping agent, the separating films separates the first photoresist and the separating pillars to protect the separating pillars, to avoid the separating pillars to be peeled off by the stripping agent, to avoid debris to be generated and enter into an evaporation chamber, to make the evaporation chamber clear and maintain the continuity and stability of films during film packaging, and to make the OLED display device flexible.

### BRIEF DESCRIPTION OF DRAWINGS

In order to describe clearly the embodiment in the present disclosure or the prior art, the following will introduce the drawings for the embodiment shortly. Obviously, the following description is only a few embodiments, for the common technical personnel in the field it is easy to acquire some other drawings without creative work.

FIG. 1 is a flowchart of a method for manufacturing a flexible OLED display device according to one exemplary embodiment of the present disclosure.

FIGS. 2A-2F are structure diagrams of the method for manufacturing the flexible OLED display device according to one exemplary embodiment of the present disclosure.

### DETAILED DESCRIPTION OF PREFERRED EMBODIMENTS

The description of following embodiment, with reference to the accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present disclosure. In the drawings, the components having similar structures are denoted by same numerals.

This application is compared with the prior art method for manufacturing the flexible OLED display device, when the photoresist is peeled off by the stripping agent after the cutting process, because the pixel defining layer and the photoresist are made of organic materials, the photoresist is peeled off by mistake by the stripping agent to contaminate the evaporation chamber and affect the continuity and stability of films during film packaging.

The following combination of the attached drawings and specific embodiments will further illustrate a method for manufacturing a flexible OLED display device.

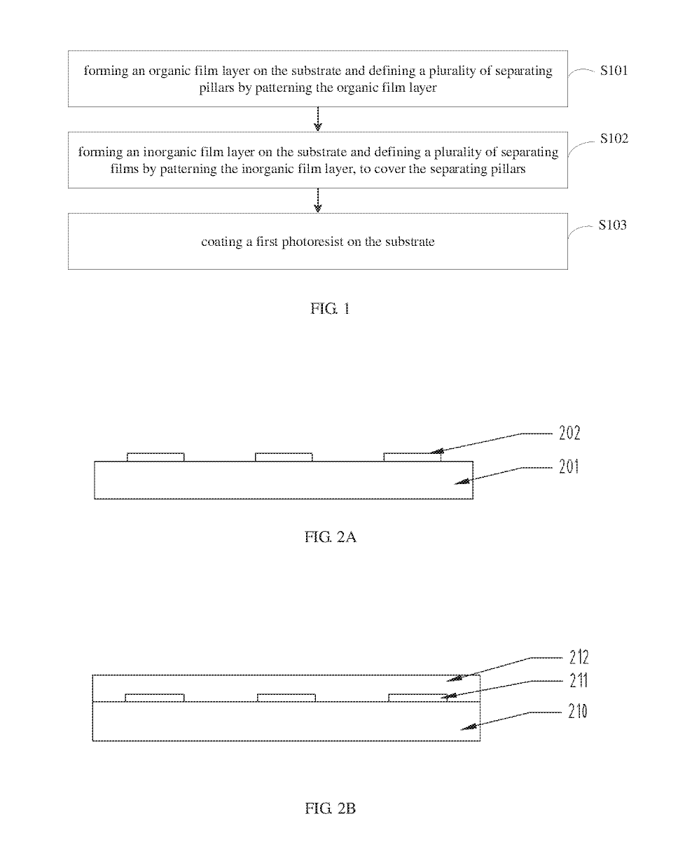

Referring to FIG. 1, an exemplary embodiment of the method for manufacturing the flexible OLED display device is provided. The method comprises a step of forming an anode metal layer on a substrate, and further comprises:

a step S101 of forming an organic film layer on the substrate and defining a plurality of separating pillars by patterning the organic film layer;

a step S102 of forming an inorganic film layer on the substrate and defining a plurality of separating films by patterning the inorganic film layer, to cover the separating pillars; and

a step S103 of coating a first photoresist on the substrate.

The following combination of the attached drawings and specific embodiments will further illustrate processes of the method for manufacturing a flexible OLED display device.

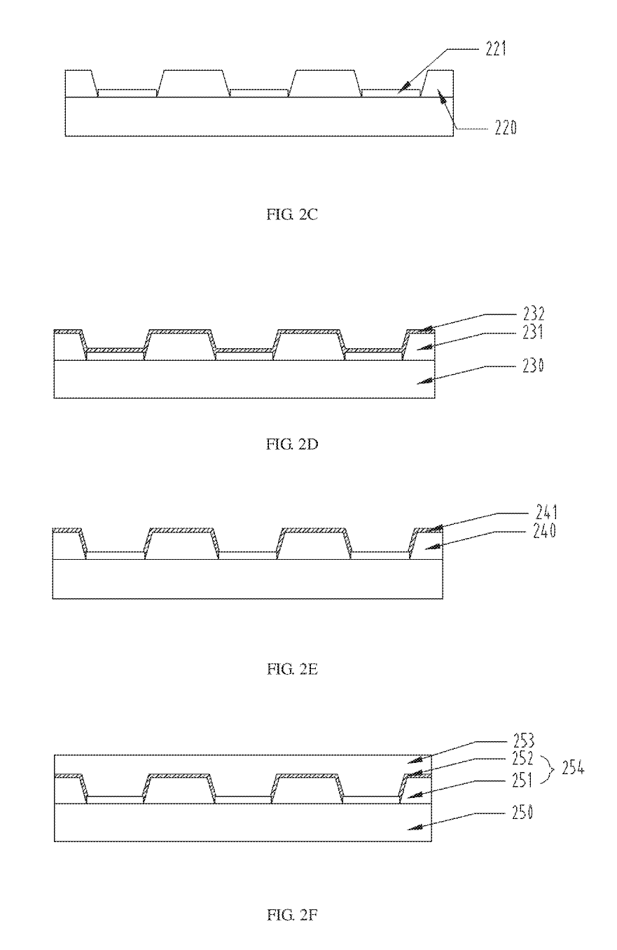

Referring to FIG. 2A, an anode metal layer is formed on the substrate 201. A plurality of anode plates 202 arranged in an array is made from the anode metal layer by patterning. A plurality of insulating gaps is defined between each two adjacent anode plates 202. The anode metal layer can be formed on the substrate 201 by another process not repeated in this application.

Referring to FIG. 2B, an organic film layer 212 is formed on the substrate 210. The organic film layer 212 can be made by other process in other embodiments of this application. The organic film layer 212 can be made of organic materials such as acrylic acid or silicon. A thickness of the organic film layer 212 is greater than a thickness of the anode plates 211.

The patterning process of this embodiment comprises: coating, exposing, developing and peeling off a photoresist. In detail, referring to FIG. 2C, a second photoresist is coated on the organic film layer, and the second photoresist is exposed and developed to retain the second photoresist corresponding to places for forming separating pillars 220 and to form a second photoresist pattern, the organic film layer not covered by the second photoresist is etched, and the second photoresist arranged on a surface of the organic film layer is peeled off to define the separating pillars 220. A shape of a cross section of each separating pillar 220 is an isosceles trapezoid. Each separating pillar 220 arranged in the insulating gaps between each two adjacent anode plates 221. A thickness of the separating pillars 220 is greater than the thickness of the anode plates 221. The shape of the cross section of each separating pillar 220 can be other shapes and not limited in this embodiment.

Referring to FIG. 2D, an inorganic film layer 232 is formed on the substrate 230 with the separating pillars 231. A thickness of the inorganic film layer 232 is less than the thickness of the organic film layer. The inorganic film layer 232 can be made of inorganic materials such as aluminum oxide (Al₂O₃), silicon nitride (SiNₓ), or silicon oxide (SiOₓ) by chemical vapor deposition (CVD) or physical vapor deposition (PVD). An identical photomask is configured to form the organic film layer and form the inorganic film layer 232. A third photoresist is coated on the inorganic film layer 232, the third photoresist is exposed and developed to retain the third photoresist corresponding to places for forming a separating film to form a third photoresist pattern, the inorganic film layer 232 not covered by the third photoresist is etched, and the third photoresist arranged on a surface of the inorganic film layer 232 is peeled off to define the separating film.

Referring to FIG. 2E, the separating film 241 is formed on a surface of the separating pillars 240. A thickness of the separating film 241 is less than the thickness of the separating pillars 240. The thickness of the separating film 241 is less than 0.5 μm.

Referring to 2F, a first photoresist 253 is formed on the substrate 250 to protect the substrate 250 and finish manufacturing the substrate. The separating film 252 covers a surface of the separating pillars 251 to separate the separating pillars 251 and the first photoresist 253 formed on a surface of the separating film 252. The separating pillars 251 and the separating film 252 defines a pixel defining layer 254 to separate sub pixels.

A light emitting layer is formed on the pixel defining layer 254 of the substrate 250. The light emitting layer is still made by evaporating. A method for manufacturing the light emitting layer is the same as conventional technology not repeated in this application. In the evaporating process, because deformations of masks, size of an evaporating substrate is difficult to match size of an array substrate. A cutting process is used from the array substrate process to the evaporating process, the first photoresist 253 is used to protect the surface of the substrate 250 to avoid debris made from the cutting process to enter into the evaporation chamber. After the cutting process, when the first photoresist 253 formed on the surface of the substrate 250 is peeled off by the stripping agent, because the separating film 252 separates the separating pillars 251 and the first photoresist 253 made of organic materials, the stripping agent stops peeling off at the separating film 252 to avoid the separating pillars 251 to be peeled off by mistake, to maintain the integrity of the pixel defining layer 254, and to make the evaporation chamber clear and maintain the continuity and stability of films during film packaging.

Further, because the separating film 252 has a poor flexibility, the pixel defining layer 254 comprises the separating pillars 251 with a thicker thickness and the separating film 252 with a thinner thickness, the separating film 252 has the thinner thickness to avoid peeling off by mistake by the stripping agent and make the OLED display device having a good flexibility.

The pixel defining layer 254 is not peeled off by mistake to maintain the certain thickness and the integrity. During making the light emitting layer, because the pixel defining layer 254 is separated to make the light emitting layer of the sub pixels evaporated to sub pixel units, to avoid problems of mixing/crosstalk in the sub pixel units, to make the evaporation chamber clear, and promote display effects of the flexible OLED display device. Because the pixel defining layer 254 has the integrity, in the subsequent process, to promote stability of packaging films attached to a surface the pixel defining layer 254.

A method for manufacturing a flexible OLED display device further comprises: a cathode layer is formed on the substrate with the light emitting layer, a place of the cathode layer is corresponding to a place of the anode layer, the light emitting layer is arranged between the anode layer and the cathode layer, a process for manufacturing the cathode layer is the same as in conventional technology not repeated in this application.

Further, a hole injection layer and/or a hole transporting layer can be formed between the anode layer and the light emitting layer. The hole injection layer and/or the hole transporting layer are the same as in conventional technology not repeated in this application. An electron injection layer and/or an electron transporting layer can be formed between the light emitting layer and the cathode layer. The electron injection layer and/or the electron transporting layer are the same as in conventional technology not repeated in this application.

A flexible OLED display device is manufactured by the method above, and comprises a substrate, an anode layer, a pixel defining layer, a transmission layer, a light emitting layer, and a cathode layer, and the pixel defining layer comprises a plurality of separating pillars and a plurality of separating films.

The present disclosure is described in detail in accordance with the above contents with the specific preferred examples. However, this present disclosure is not limited to the specific examples. For a person of ordinary skill in the art, on the premise of keeping the conception of the present disclosure, the technical personnel can also make simple deductions or replacements, all of which should be considered to belong to the protection scope of the present disclosure.

What is claimed is:

1. A method for manufacturing a flexible organic light emitting diode (OLED) display device comprising a step of forming an anode metal layer on a substrate, and further comprising:
a step S101 of forming an organic film layer on the substrate and defining a plurality of separating pillars by patterning the organic film layer;
a step S102 of forming an inorganic film layer on the substrate and defining a plurality of separating films by patterning the inorganic film layer, to cover the separating pillars; and
a step S103 of coating a first photoresist oil the substrate;
wherein an identical photomask is configured to form the organic film layer and form the inorganic film layer.

2. The method of claim 1, wherein the step S101 comprises:
coating a second photoresist on the organic film layer, exposing and developing the second photoresist to form a second photoresist pattern, etching the organic film layer not covered by the second photoresist, and peeling off the second photoresist arranged on a surface of the organic film layer to define the separating pillars.

3. The method of claim 2, wherein the step S102 comprises:
coating a third photoresist on the inorganic film layer, exposing and developing the third photoresist to form a third photoresist pattern, etching the inorganic film layer not covered by the third photoresist, and peeling off the third photoresist arranged on a surface of the inorganic film layer to define the separating films.

4. The method of claim 1, wherein the separating films are arranged on surfaces of the separating pillars.

5. The method of claim 4, wherein the anode metal layer comprises a plurality of anode plates arranged in an array, each of the separating pillars and one of the separating films corresponding to the separating pillar is arranged between two of the anode plates adjacent to each other.

6. The method of claim 1, wherein the inorganic film layer is made of one or more of Al₂O₃, SiNₓ, and SiOₓ.

7. The method of claim 1, wherein a thickness of the separating films is less than a thickness of the separating pillars.

8. The method of claim 7, wherein the thickness of the separating films is less than or equal to 0.5 μm.

9. A method for manufacturing a flexible organic light emitting diode (OLED) display device comprising a step of forming an anode metal layer on a substrate, and further comprising:
a step S101 of forming an organic film layer on substrate and defining a plurality of separating pillars by patterning the organic film layer;
a step S102 of forming an inorganic film layer on the substrate and defining a plurality of separating films by patterning the inorganic film layer, to cover the separating pillars; and
a step S103 of coating a first photoresist on the substrate.

10. The method of claim 9, wherein the step S101 comprises:
coating a second photoresist on the organic film layer, exposing and developing the second photoresist to form a second photoresist pattern, etching the organic film layer not covered by the second photoresist, and peeling off the second photoresist arranged on a surface of the organic film layer to define the separating pillars.

11. The method of claim 10, wherein the step S102 comprises:
coating a third photoresist on the inorganic film layer, exposing and developing the third photoresist to form a third photoresist pattern, etching the inorganic film layer not covered by the third photoresist, and peeling off the third photoresist arranged on a surface of the inorganic film layer to define the separating films.

12. The method of claim 9, wherein the separating films are arranged on surfaces of the separating pillars.

13. The method of claim 12, wherein the anode metal layer comprises a plurality of anode plates arranged in an array, each of the separating pillars and one of the separating films corresponding to the separating pillar is arranged between two of the anode plates adjacent to each other.

14. The method of claim 9, wherein the inorganic film layer is made of one or more of Al2O3, SiNx, and SiOx.

15. The method of claim 9, wherein a thickness of the separating films is less than a thickness of the separating pillars.

16. The method of claim 15, wherein the thickness of the separating films is less than or equal to 0.5 μm.

17. A flexible organic light emitting diode (OLED) display device manufactured by the method of claim 1, wherein the flexible OLED display device comprising a substrate, an anode layer, a pixel defining layer, a transmission layer, a light emitting layer, and a cathode layer, wherein the pixel defining layer comprises a plurality of separating pillars and a plurality of separating films.
